(19) United States
(12) Patent Application Publication
(10) Pub. No.: US 2019/0027296 A1
(43) Pub. Date: Jan. 24, 2019

(54) WIRING BOARD, PLANAR TRANSFORMER, AND METHOD OF MANUFACTURING THE WIRING BOARD

(71) Applicant: NGK SPARK PLUG CO., LTD., Nagoya-shi (JP)

(72) Inventor: Masahito MORITA, Yokohama-shi (JP)

(21) Appl. No.: 16/037,074

(22) Filed: Jul. 17, 2018

(30) Foreign Application Priority Data
Jul. 21, 2017 (JP) 2017-142015

(51) Int. Cl. H01F 27/28; H01F 27/29; H05K 1/16; H05K 3/40

(52) U.S. Cl. CPC H01F 27/2804; H01F 27/29; H01F 2027/2819; H05K 3/4069; H05K 1/165

(57) ABSTRACT

The present disclosure provides a wiring board including at least one insulating layer that has a front surface and a back surface, a first wiring layer that is disposed on a front surface side of the at least one insulating layer, a second wiring layer that is disposed on a back surface side of the insulating layer where the first wiring layer is disposed, and a connection conductor that electrically connects the first wiring layer and the second wiring layer to each other. The insulating layer has a through hole that extends through the insulating layer in a thickness direction. The connection conductor includes a metal member that is disposed in the through hole, and a joining portion that covers at least a part of an outer surface of the metal member and that joins the metal member to the first wiring layer and to the second wiring layer.

### CROSS REFERENCE TO RELATED APPLICATION

The present application claims priority to Japanese Patent Application no. 2017-142015, which was filed on Jul. 21, 2017, the disclosure of which is herein incorporated by reference in its entirety.

### BACKGROUND OF THE INVENTION

### 1. Field of the Invention

The present disclosure relates to a wiring board, a planar transformer, and a method of manufacturing the wiring board.

### 2. Description of the Related Art

As a method of manufacturing a multi-layer wiring board including a plurality of insulating layers and a plurality of wiring layers that are alternately laminated to each other, a method of forming the wiring layers by performing printing on the insulating layers using a metal paste, and then by firing is known (refer to PTL 1). In this method, vias, which are connection conductors that cause continuity between the plurality of wiring layers, are also formed by firing a metal paste.

### RELATED ART DOCUMENT

Patent Document 1 is Japanese Unexamined Patent Application Publication No. 6-204039.

In the above-described multi-layer wiring board, in order to reduce electrical resistance, there may be a demand for increasing the diameter of the connection conductors in accordance with an increase in the wall thickness of the wiring layers. However, when connection conductors having large diameters are formed by performing the above-described method, stress is generated during the firing due to differences between the thermal expansion coefficient of the materials of which the connection conductors are made and the thermal expansion coefficient of the insulating layers, as a result of which defects, such as cracks or breakages, tend to occur in the insulating layers. In addition, it may be difficult to form the connection conductors due to the formation of gaps (so-called voids) in the connection conductors.

### BRIEF SUMMARY OF THE INVENTION

An object of an aspect of the present disclosure is to provide a wiring board that makes it possible to suppress the occurrence of defects in an insulating layer and the formation of voids in a connection conductor while increasing the diameter of the connection conductor.

According to a form of the present disclosure, there is provided a wiring board including at least one insulating layer that has a front surface and a back surface, a first wiring layer that is disposed on a front surface side of the at least one insulating layer, a second wiring layer that is disposed on a back surface side of the insulating layer where the first wiring layer is disposed, and a connection conductor that electrically connects the first wiring layer and the second wiring layer to each other. The insulating layer has a through hole that extends through the insulating layer in a thickness direction. The connection conductor includes a metal member that is disposed in the through hole, and a joining portion that covers at least a part of an outer surface of the metal member and that joins the metal member to the first wiring layer and to the second wiring layer. In other words, the wiring board includes at least one insulating layer that has a front surface and a back surface, the at least one insulating layer defining a through hole that extends through the insulating layer in a thickness direction. The wiring board further includes a first wiring layer disposed adjacent to a front surface side of the at least one insulating layer, a second wiring layer disposed adjacent to a back surface side of the at least one insulating layer, and a connection conductor electrically connecting the first wiring layer to the second wiring layer. The connection conductor includes a metal member disposed in the through hole of the at least one insulating layer, and a joining portion that covers at least a part of an outer surface of the metal member and that joins the metal member to the first wiring layer and to the second wiring layer.

According to such a structure, by using the connection conductor where the metal member is joined to the wiring layers by the joining portion, it is possible to suppress the formation of voids in the connection conductor. In addition, since it is not necessary to fire the connection conductor, it is possible to suppress the occurrence of defects, such as cracks or breakages, in the insulating layer resulting from stress caused by differences between the thermal expansion coefficient of the insulating layer and the thermal expansion coefficient of the connection conductor. Therefore, it is possible to easily increase the diameter of the connection conductor.

In the form of the present disclosure, in the connection conductor, a volume of the metal member may be greater than a volume of the joining portion. According to such a structure, it is possible to more effectively suppress the formation of voids in the connection conductor.

In the form of the present disclosure, the metal member may be a block body or a spherical body. According to such a structure, it is possible to easily and reliably form the connection conductor that electrically connects the wiring layers to each other.

In the form of the present disclosure, an area of the metal member projected onto a virtual plane that is perpendicular to the thickness direction of the insulating layer may be smaller than an opening area of the through hole. According to such a structure, when the metal member thermally expands due to changes in temperature, the metal member makes it is possible to suppress the generation of stress at an inner wall of the through hole. As a result, it is possible to suppress, for example, breakage in the insulating layer.

In the form of the present disclosure, the metal member need not be fixed to an inner wall of the insulating layer that forms (i.e., defines) the through hole. According to such a structure, since the metal member and the insulating layer can be individually displaced, it is possible to suppress the generation of stress caused by differences between the thermal expansion coefficient of the metal member and the thermal expansion coefficient of the insulating layer.

In the form of the present disclosure, at least one of the first wiring layer and the second wiring layer may include an unfixing region that is not fixed to the insulating layer adjacent thereto and a fixing region that is fixed to the insulating layer adjacent thereto. Alternatively, the first wiring layer and the second wiring layer need not be fixed to the insulating layer adjacent thereto. According to such a structure, when the wiring layer and the insulating layer have expanded or contracted due to changes in temperature, differences between the deformation amount of the wiring layer and the deformation amount of the insulating layer caused by differences between the thermal expansion coefficients can be absorbed by the unfixing region that is not fixed to the insulating layer. Therefore, stress that is generated between the insulating layer and the wiring layer is reduced, and defects, such as cracks, in the insulating layer are suppressed.

In the form of the present disclosure, a main constituent of the first wiring layer and the second wiring layer may be copper. According to such a structure, it is possible to acquire a highly reliable wiring board that is low in cost, has a high electrical conductivity, and a high thermal conductivity.

In the form of the present disclosure, a main constituent of the insulating layer may be ceramic. According to such a structure, since the flatness of the insulating layer is increased, it is possible to arrange wires with high density at the insulating layer. Further, it is possible to obtain high insulation property.

In a different form of the present disclosure, there is provided a method of manufacturing a wiring board that includes at least one insulating layer that has a front surface and a back surface, a first wiring layer that is disposed on (i.e., adjacent to) a front surface side of the at least one insulating layer, a second wiring layer that is disposed on (i.e., adjacent to) a back surface side of the insulating layer where the first wiring layer is disposed (i.e., the at least one insulating layer), and a connection conductor that electrically connects the first wiring layer and the second wiring layer to each other. The method includes a step of providing (i.e., forming) a through hole in the insulating layer, the through hole extending through the insulating layer in a thickness direction; a step of disposing a metal member in the through hole, at least a part of an outer surface of the metal member being covered by a joining portion; a step of disposing the first wiring layer on (adjacent to) the front surface side of the insulating layer and disposing the second wiring layer on (adjacent to) the back surface side of the insulating layer; and a step of joining the metal member to the first wiring layer and to the second wiring layer by (with) the joining portion.

According to such a structure, it is possible to easily and reliably manufacture a wiring board in which the formation voids in the connection conductor is suppressed and in which the occurrence of defects, such as cracks or breakages, in the insulating layer is suppressed.

### BRIEF DESCRIPTION OF THE DRAWINGS

Illustrative aspects of the invention will be described in detail with reference to the following figures wherein:

FIG. 1 is a schematic sectional view of a wiring board of an embodiment.

FIG. 2A is a schematic partial enlarged sectional view of the vicinity of connection conductors in the wiring board in FIG. 1; and FIG. 2B is a schematic sectional view along line IIB-IIB of FIG. 2A.

FIG. 3 is a flowchart of a method of manufacturing the wiring board in FIG. 1.

FIG. 4 is a schematic sectional view, corresponding to FIG. 2A, of a wiring board of an embodiment differing from that shown in FIG. 1.

FIG. 5 is a schematic sectional view of a wiring board of an embodiment differing from those shown in FIGS. 1 and 4.

### DETAILED DESCRIPTION OF EXEMPLARY EMBODIMENTS OF THE INVENTION

Embodiments to which the present disclosure is applied are described below by using the drawings.

### A. First Embodiment

Wiring Board

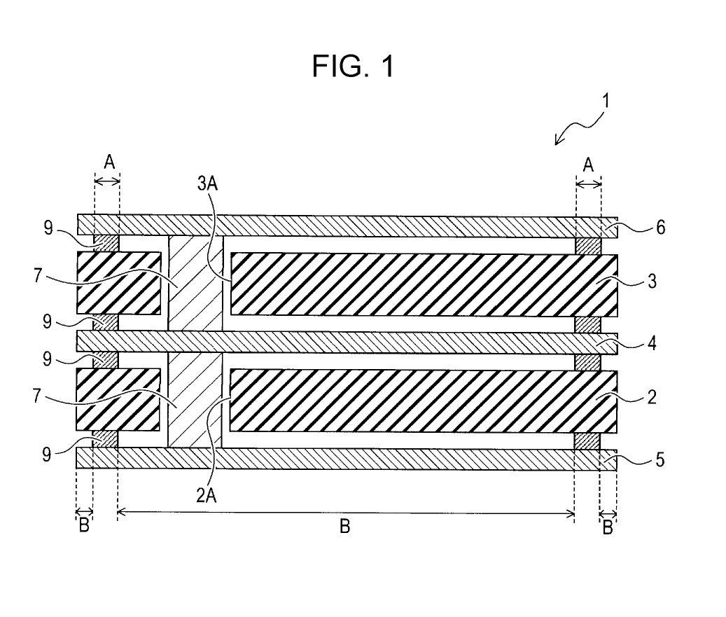

A wiring board 1 shown in FIG. 1 includes a plurality of insulating layers (a first insulating layer 2 and a second insulating layer 3), a plurality of wiring layers (a first wiring layer 4, a second wiring layer 5, and a third wiring layer 6), a plurality of connection conductors 7 that each connect the corresponding wiring layers to each other, and a plurality of wiring layer fixing members 9.

In the embodiment, as an example of the present disclosure, the wiring board 1 is described as one having a multi-layer structure including two insulating layers and three wiring layers. However, the number of insulating layers and the number of wiring layers in the wiring board of the present disclosure are not limited thereto.

Due to the design of a pattern of the wiring layers, the wiring board 1 is used in, for example, a transformer, an insulated gate bipolar transistor (IGBT), a light emitting diode (LED) illumination device, a power transistor, or a motor. The wiring board 1 is particularly suitable for use in high-voltage and large-current applications.

Insulating Layers

The first insulating layer 2 and the second insulating layer 3 each have a front surface and a back surface. The main constituent of each of the first insulating layer 2 and the second insulating layer 3 is ceramic. The term “main constituent” means a constituent that is contained by 80 mass % or greater.

Examples of ceramic of which the first insulating layer 2 and the second insulating layer 3 are made include alumina, beryllia, aluminum nitride, boron nitride, silicon nitride, silicon carbide, and LTCC (Low Temperature Co-fired Ceramic). Such ceramics may be singly used, or combinations of two or more types of such ceramics may be used.

The first wiring layer 4 that is adjacent to the first insulating layer 2 is disposed on a front surface side of the first insulating layer 2. The second wiring layer 5 that is adjacent to the first insulating layer 2 is disposed on a back surface side of the first insulating layer 2. The second insulating layer 3 is disposed on the front surface side of the first insulating layer 2 with the first wiring layer 4 interposed therebetween. The third wiring layer 6 that is adjacent to the second insulating layer 3 is disposed on a front surface side of the second insulating layer 3.

The first insulating layer 2 has at least one through hole 2A that extends through the first insulating layer 2 in a thickness direction. The second insulating layer 3 has at least one through hole 3A that extends through the second insulating layer 3 in the thickness direction. The through holes 2A and 3A are so-called via holes where vias that electrically connect the wiring layers to each other are formed. In the embodiment, the through hole 2A in the first insulating layer 2 and the through hole 3A in the second insulating layer 3 are provided in corresponding positions as viewed in the thickness direction of the insulating layers 2 and 3 (that is, in plan view), and have the same diameter.

Wiring Layers

The first wiring layer 4, the second wiring layer 5, and the third wiring layer 6 are electrical conductive, and each contain a metal as a main constituent. Examples of metal include copper, aluminum, silver, gold, platinum, nickel, titanium, chromium, molybdenum, tungsten, and alloys thereof. Among these metals, from the viewpoints of cost, electrical conductivity, thermal conductivity, and mechanical strength, copper is desirable. Therefore, a copper foil or a copper plate can be suitably used as each of the wiring layers 4, 5, and 6.

The first wiring layer 4 is disposed on the front surface side of the first insulating layer 2. The first wiring layer 4 includes fixing regions A that are fixed to the first insulating layer 2 adjacent thereto, and unfixing regions B that are not fixed to the first insulating layer 2 adjacent thereto. The first wiring layer 4 is an inner wiring layer that is disposed between two insulating layers, that is, the insulating layers 2 and 3.

The second wiring layer 5 is disposed on the back surface side of the first insulating layer 2. The third wiring layer 6 is disposed on the front surface side of the second insulating layer 3. Similarly to the first wiring layer 4, the second wiring layer 5 and the third wiring layer 6 each include fixing regions A that are fixed to the insulating layer adjacent thereto, and unfixing regions B that are not fixed to the insulating layer adjacent thereto. The details of the fixing regions A and the unfixing regions B are described later.

Connection Conductors

The plurality of connection conductors 7 are each disposed in a corresponding one of the through hole 2A of the first insulating layer 2 and the through hole 3A in the second insulating layer 3. The connection conductors 7 are so-called vias that each electrically connect the first wiring layer 4 to the second wiring layer 5 or to the third wiring layer 6. The connection conductors 7 each join the first wiring layer 4 to the second wiring layer 5 or to the third wiring layer 6.

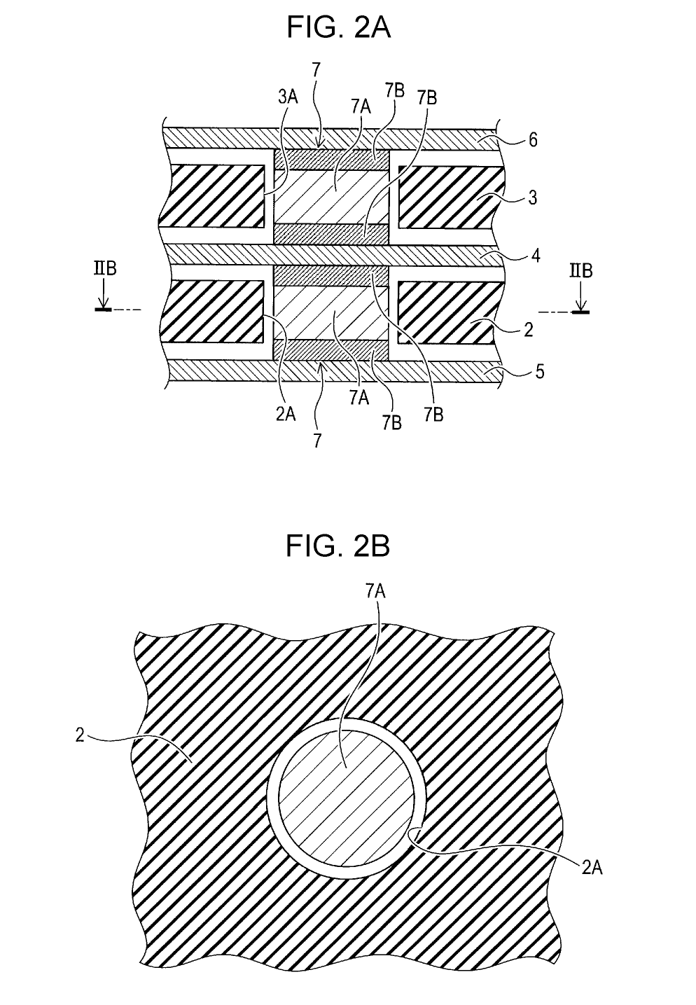

As shown in FIG. 2A, each connection conductor 7 includes one metal member 7A and a joining portion 7B. Although, in the description below, the connection conductor 7 that is disposed in the through hole 2A of the first insulating layer 2 is described, the description below similarly also applies to the connection conductor 7 that is disposed in the through hole 3A of the second insulating layer 3.

One metal member 7A is disposed in the through hole 2A. One metal member 7A electrically connects the first wiring layer 4 and the second wiring layer 5 via the joining portion 7B.

The material of the metal member 7A is not particularly limited to certain materials, and may be the same metal usable in the first wiring layer 4 and the second wiring layer 5. However, it is desirable that the material of the metal member 7A be the same as the main constituent of the first wiring layer 4 and the second wiring layer 5. This makes it possible to reduce stress that is generated between the connection conductor 7 and the wiring layers 4 and 5 when changes in temperature occur.

In the embodiment, as shown in FIG. 2B, the metal member 7A is a plate-shaped block body having a planar shape that is circular. Examples of the block body include a columnar-shaped body, a plate-shaped body, and a foil-shaped body. The area of the metal member 7A projected onto a virtual plane that is perpendicular to a thickness direction of the first insulating layer 2 is smaller than the opening area of the through hole 2A. That is, the diameter of the planar shape of the metal member 7A is smaller than the diameter of the through hole 2A. The planar shape of the metal member 7A is not limited to a circular shape, and may be an elliptical shape or a polygonal shape.

It is desirable that the maximum width of the metal member 7A be, for example, greater than or equal to 60% and less than or equal to 85% of the diameter of the through hole 2A. When the maximum width is less than 60%, a gap between an inner wall of the first insulating layer 2 that forms the through hole 2A and the metal member 7A becomes too large. Therefore, the metal member 7A moves excessively in the through hole 2A, and stress may be generated in a joining portion between the first wiring layer 4 and the metal member 7A and between a joining portion between the second wiring layer 5 and the metal member 7A. When the maximum width is greater than 85% and the metal member 7A thermally expands due to changes in temperature, the metal member 7A may produce stress in the inner wall of the first insulating layer 2 that forms the through hole 2A.

In the embodiment, the metal member 7A is separated from the inner wall of the first insulating layer 2 that forms the through hole 2A, and is not fixed to the inner wall of the first insulating layer 2 that forms the through hole 2A. The thickness of the metal member 7A is less than the depth of the through hole 2A (that is, the thickness of the first insulating layer 2 at a portion where the through hole 2A is formed).

The joining portion 7B is electrical conductive, and electrically connects the metal member 7A to the first wiring layer 4 and the metal member 7A to the second wiring layer 5. The joining portion 7B may be, for example, a metal brazing material, such as a silver-copper alloy, or a solder material, such as a tin-silver-copper alloy.

As shown in FIG. 2A, the joining portion 7B covers at least a region on a front surface side and a back surface side of the metal member 7A in the thickness direction of the insulating layer 2 of an outer surface of the metal member 7A. In other words, the joining portion 7B is joined to the front surface of the metal member 7A facing the first wiring layer 4 and to the back surface of the metal member 7A facing the second wiring layer 5.

The joining portion 7B joins the metal member 7A to the first wiring layer 4 and the metal member 7A to the second wiring layer 5. That is, the joining portion 7B is disposed between the front surface of the metal member 7A and a back surface of the first wiring layer 4, and between the back surface of the metal member 7A and a front surface of the second wiring layer 5. The joining portion 7B is not provided on a side surface of the metal member 7A (that is, surfaces facing the inner wall of the through hole 2A). In addition, the joining portion 7B is not joined to the first insulating layer 2. A gap exists between the connection portion 7 and the inner wall of the first insulating layer 2 that forms the through hole 2A. In one connection conductor 7, the volume of the metal member 7A is greater than the volume of the joining portion 7B.

Wiring Layer Fixing Members

As shown in FIG. 1, the plurality of wiring layer fixing members 9 are each disposed between the first wiring layer 4 and the first insulating layer 2, between the first wiring layer 4 and the second insulating layer 3, between the second wiring layer 5 and the first insulating layer 2, or between the third wiring layer 6 and the second insulating layer 3.

For example, similarly to the joining portions 7B of the connection conductors 7, the plurality of wiring layer fixing members 9 are made of a metal brazing material or a solder material. The first wiring layer 4 is joined to the first insulating layer 2 and the second insulating layer 3 by the wiring layer fixing members 9 adjacent thereto.

Fixing Regions and Unfixing Regions

As described above, the plurality of wiring layers 4, 5, and 6 each include the fixing regions A and the unfixing regions B. In the embodiment, the fixing regions A and the unfixing regions B of the wiring layer 4, the fixing regions A and the unfixing regions B of the wiring layer 5, and the fixing regions A and the unfixing regions B of the wiring layer 6 are disposed at corresponding locations in plan view. Although in the description below, each region is described by using the first wiring layer 4, the following description also similarly applies to the other wiring layers.

The fixing regions A are regions where the first wiring layer 4 is fixed to the first insulating layer 2. More specifically, as shown in FIG. 1, in the first wiring layer 4, regions where the wiring layer fixing members 9 are joined form the fixing regions A. The planar shape of the fixing regions A is not particularly limited to certain shapes.

Regions where the wiring layer fixing members 9 are not joined are included in the unfixing regions B. In the embodiment, since the connection connectors 7 are not joined to the insulating layers 2 and 3, joining portions of the wiring layer 4 with the corresponding connection connectors 7, a joining portion of the wiring layer 5 with the corresponding connection conductor 7, and a joining portion of the wiring layer 6 with the corresponding connection conductor 7 are included in the unfixing regions B.

The maximum distance from the gravity center of each fixing region A to an outer edge of each fixing region A as viewed from the thickness direction of the first wiring layer 4 is desirably 7 mm or less and more desirably 5 mm or less. When the maximum distance is too large, cracks and breakages caused by differences between the thermal expansion coefficient of the insulating layers and the thermal expansion coefficient of the wiring layers may occur in the first insulating layer 2 and the second insulating layer 3.

The expression “the maximum distance from the gravity center of a fixing region to an outer edge of the fixing region” refers to, of the lengths of line segments extending from the gravity center of the fixing region to the outer edge of the fixing region (may also be called “extended line segments” below), the length of the longest extended line segment. When an unfixing region is included within the fixing region (for example, when the fixing region has a ring shape), first, a virtual gravity center including the unfixing region included in the fixing region is determined, and the extended line segment is acquired. Next, of the length of the acquired extended line segment, the length of a portion passing through the unfixing region is excluded from the length. That is, the length of the extended line segment corresponds to the length of only the portion included in the fixing region.

In the unfixing regions B, in the embodiment, each of the wiring layers 4, 5, and 6 is disposed apart from the first insulating layer 2 or the second insulating layer 3. However, each of the wiring layers 4, 5, and 6 may contact the first insulating layer 2 or the second insulating layer 3. That is, in the unfixing regions B, as long as the wiring layers and the insulating layers are capable of being individually displaced in a planar direction, the wiring layers and the insulating layers need not be disposed apart from each other as they are in each figure, and may contact each other.

Method of Manufacturing Wiring Board

Next, a method of manufacturing the wiring board 1 is described.

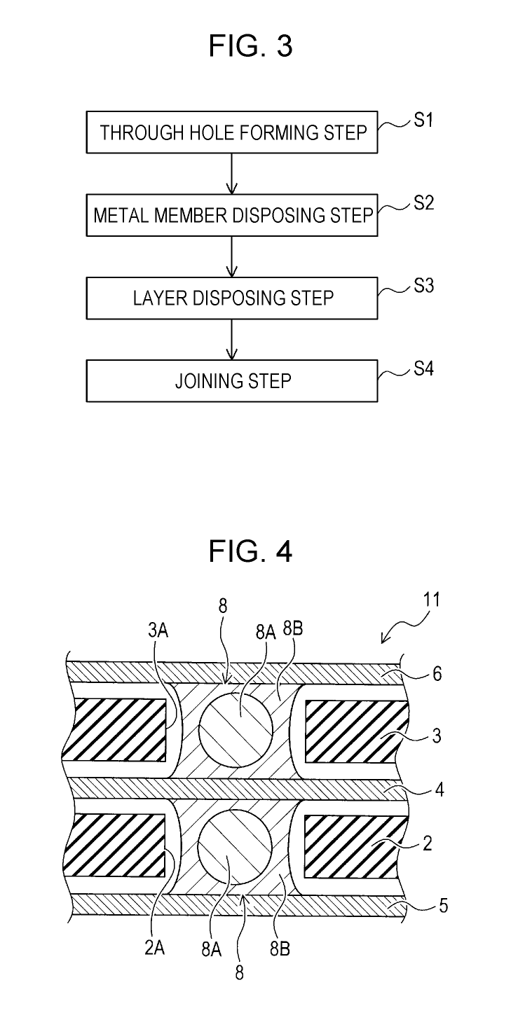

The wiring board 1 is acquired by performing a manufacturing method including a through hole forming step S1, a metal member disposing step S2, a layer disposing step S3, and a joining step S4, which are shown in FIG. 3.

Through Hole Forming Step

In this step, a plurality of insulating layers are formed, and through holes that extend through the corresponding insulating layers in the thickness direction are formed in the corresponding insulating layers.

In this step, first, unsintered ceramic is molded into the form of a ceramic substrate. More specifically, first, ceramic powder, an organic binder, a solvent, and a plasticizer or other additives are mixed with each other to acquire a slurry. Next, by molding the slurry into the form of a sheet by a publicly known method, the unsintered ceramic having the form of a substrate (a so-called ceramic green sheet) is acquired.

Through holes 2A and 3A are formed in the acquired ceramic green sheet by, for example, punching. Then, the ceramic green sheet is sintered. This forms ceramic insulating layers 2 and 3.

Metal Member Disposing Step

In this step, each metal member 7A having at least a part of its outer surface (a front surface and a back surface in the embodiment) covered with a joining portion 7B is disposed in a corresponding one of the through hole 2A and the through hole 3A. More specifically, after each joining portion 7B, made of a metal brazing material or a solder material, has been laminated on the front surface and the back surface of the corresponding metal member 7A by, for example, coating, each metal member 7A is disposed in a corresponding one of the through hole 2A and the through hole 3A.

Layer Disposing Step

In this step, the insulating layers 2 and 3, where the corresponding metal members 7A are disposed, and the wiring layers 4, 5, and 6 are alternately placed one above the other.

That is, in this step, the first wiring layer 4 is disposed on a front surface side of the first insulating layer 2, and the second wiring layer 5 is disposed on a back surface side of the first insulating layer 2. In addition, the second insulating layer 3 is disposed on the front surface side of the first wiring layer 4, and the third wiring layer 6 is disposed on a front surface side of the second insulating layer 3. A plurality of wiring layer fixing members 9 are each disposed between corresponding wiring layers.

The layer disposing step S3 may be performed before the metal member disposing step S2. The metal member disposing step S2 and the layer disposing step S3 may be performed at the same time. For example, it is possible to, after disposing the second wiring layer 5 on the back surface side of the first insulating layer 2, dispose the metal member 7A in the through hole 2A, and then, dispose the first wiring layer 4 on the front surface side of the first insulating layer 2.

Joining Step

In this step, the joining portion 7B is melted and solidified, and the metal member 7A is joined to the first wiring layer 4 and the second wiring layer 5.

More specifically, a multilayer body including the layers placed one on top of the other and acquired in the layer disposing step S3 is heated. This causes connection conductors 7 to be formed and the plurality of insulating layers 2 and 3 and the plurality of wiring layers 4, 5, and 6 to be joined to each other by the corresponding wiring layer fixing members 9.

Similarly to the joining portions 7B, the plurality of wiring layer fixing members 9 may be made of, for example, a metal brazing material. The wiring layer fixing members 9 and the insulating layers 2 and 3 can be easily fixed to each other when metallized layers (not shown) are formed in a range corresponding to the fixing regions A of the insulating layers 2 and 3.

Although, in the above-described joining step, the joining portions 7B are melted and solidified, a portion between an inner wall of the insulating layer 2 that forms the through hole 2A and the metal member 7A is not fixed by the joining portion 7B. This is to prevent leakage of the joining portion 7B from spreading without forming a metal layer on an inner wall surface of the insulating layer 2 that forms the through hole 2A.

Effects

The embodiment described in detail above provides the following effects.

(1a) By using the connection conductor 7 where the metal member 7A is joined to the wiring layers 4 and 5 by the corresponding joining portion 7B and the connection conductor 7 where the metal member 7A is joined to the wiring layers 4 and 6 by the corresponding joining portion 7B, the formation of voids in the connection conductors 7 is suppressed. Since it is not necessary to fire and form the connection conductors 7 at the same time as or separately from the insulating layers, it is possible to suppress the occurrence of defects, such as cracks or breakages, in the insulating layers 2 and 3 resulting from stress caused by differences between the thermal expansion coefficient of the insulating layers 2 and 3 and the thermal expansion coefficient of the connection conductors 7. Therefore, it is possible to increase the diameter of the connection conductors 7 and to provide, for example, a high-quality transformer in which the wiring board 1 deals with a high voltage and a large current.

(1b) Since the volume of the metal members 7A is greater than the volume of the joining portions 7B, it is possible to more effectively suppress the formation of voids in the connection conductors 7.

(1c) Since each metal member 7A is a block body, only the thickness thereof can be easily adjusted in accordance with the depth of the through holes 2A and 3B. Therefore, it is possible to easily and reliably form the connection conductors 7 that cause continuity between corresponding wiring layers.

(1d) Since the area of each metal member 7A projected onto a virtual plane that is perpendicular to the thickness direction of the insulating layer 2 or the insulating layer 3 is smaller than the opening area of the through hole 2A or the opening area of the through hole 3A, when the metal members 7A thermally expand due to changes in temperature, it is possible to suppress the generation of stress caused by the metal members 7A at the inner wall of the insulating layer 2 that forms the through hole 2A and at the inner wall of the insulating layer 3 that forms the through hole 3A. As a result, it is possible to suppress, for example, breakage in the insulating layers 2 and 3.

(1e) Since each metal member 7A is not fixed to the inner wall of the insulating layer 2 that forms the through hole 2A or the inner wall of the insulating layer 3 that forms the through hole 3A, the metal members 7A and the insulating layers 2 and 3 can be individually displaced. Therefore, it is possible to suppress the generation of stress caused by differences between the thermal expansion coefficient of the metal members 7A and the thermal expansion coefficient of the insulating layers 2 and 3.

(1f) Since the wiring layers 4, 5, and 6 each include the unfixing regions B, when the wiring layers 4, 5, and 6 and the insulating layers 2 and 3 have expanded or contracted due to changes in temperature, the difference between the deformation amount of each of the wiring layers 4, 5, and 6 and the deformation amount of each of the insulating layers 2 and 3 caused by differences between the thermal expansion coefficient of each of the wiring layers 4, 5, and 6 and the thermal expansion coefficient of each of the insulating layers 2 and 3 can be absorbed by the unfixing regions B that are not fixed to the insulating layer 2 or the insulating layer 3. Therefore, stress that is generated between the insulating layer 2 and the wiring layer 4, between the insulating layer 2 and the wiring layer 5, between the insulating layer 3 and the wiring layer 4, and between the insulating layer 3 and the wiring layer 6 is reduced, and defects, such as cracks or breakages, in the insulating layers 2 and 3 are suppressed.

Therefore, for example, it is possible to use alumina (having a thermal expansion coefficient of 7.6×10⁻⁶ m/K) as the main constituent of each insulating layer, and use copper having a high electrical conductivity and a high thermal conductivity (and having a thermal expansion coefficient of 17×10⁻⁶ m/K) as the main constituent of each wiring layer.

(1g) Since the main constituent of each of the first insulating layer 2 and the second insulating layer 3 is ceramic, the flatness of each of the insulating layers 2 and 3 is increased. Therefore, it is possible to arrange wires with high density at the insulating layers 2 and 3. Further, it is possible to obtain high insulation property. Consequently, even if a relatively large electrical current flows through the wiring layers 4, 5, and 6, it is possible to reliably electrically insulate portions between the wiring layers 4, 5, and 6.

### B. Second Embodiment

Wiring Board

A wiring board 11 shown in FIG. 4 includes a plurality of insulating layers (a first insulating layer 2 and a second insulating layer 3), a plurality of wiring layers (a first wiring layer 4, a second wiring layer 5, and a third wiring layer 6), and a plurality of connection conductors 8 that each connect the corresponding wiring layers. Since the plurality of insulating layers 2 and 3 and the plurality of wiring layers 4, 5, and 6 are similar to those of the wiring board 1 of FIG. 1, they are given the same reference numerals and are not described.

Connection Conductors

Similarly to the connection conductors 7 in FIG. 1, the connection conductors 8 are each disposed in a corresponding one of the through hole 2A of the first insulating layer 2 and the through hole 3A of the second insulating layer 3. The connection conductors 8 each electrically connect the first wiring layer 4 and the second wiring layer 5 to each other or the first wiring layer 4 and the third wiring layer 6 to each other. The connection conductors 8 each join the first wiring layer 4 to the second wiring layer 5 or to the third wiring layer 6.

Each connection conductor 8 includes a metal member BA and a joining portion 8B. The material of each metal member 8A and the material of each joining portion 8B are the same as that of each metal member 7A and that of each joining portion 7B in FIG. 2, respectively. One metal member 7A is disposed in one through hole 2A.

In the embodiment, each metal member 8A is a spherical body as shown in FIG. 4. The diameter of each metal member 8A is smaller than the diameter and the depth of the through hole 2A or the diameter and the depth of the through hole 3A. Each metal member 8A is separated from an inner wall of the insulating layer 2 that forms the through hole 2A or an inner wall of the insulating layer 3 that forms the through hole 3A. Although the entire outer surface of each metal member 8A is covered by the joining portion 8B, each metal member 8A need not be joined to a corresponding one of the inner wall of the insulating layer 2 that forms the through hole 2A and the inner wall of the insulating layer 3 that forms the through hole 3A.

The joining portion 8B electrically connects the metal member 8A to the first wiring layer 4 and to the second wiring layer 5. The joining portion 8B joins the entire outer surface of the metal member 8A to a part of a back surface of the first wiring layer 4 and to a part of a front surface of the second wiring layer 5 (that is, parts that overlap the through hole 2A and the through hole 3A). The joining portions 8B are not joined to the first insulating layer 2 and the second insulating layer 3.

Effects

The embodiment described in detail above provides the following effects.

(2a) Since the metal members 8A are spherical bodies, when disposing each metal member 8A into a corresponding one of the through hole 2A and the through hole 3A, it is not necessary to adjust the orientation (that is, the posture) of each metal member 8A. Therefore, it is possible to easily and reliably form the connection conductors 8 that cause continuity between corresponding wiring layers 4.

### C. Third Embodiment

Wiring Board

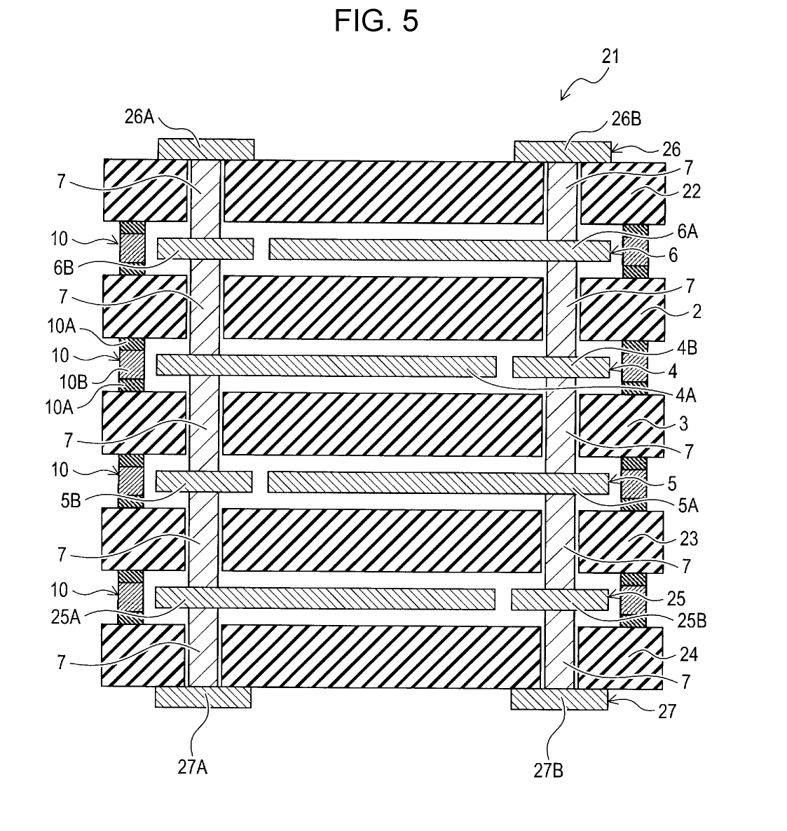

A wiring board 21 shown in FIG. 5 includes a plurality of insulating layers (a first insulating layer 2, a second insulating layer 3, a third insulating layer 22, a fourth insulating layer 23, and a fifth insulating layer 24), a plurality of wiring layers (a first wiring layer 4, a second wiring layer 5, a third wiring layer 6, a fourth wiring layer 25, a fifth wiring layer 26, and a sixth wiring layer 27), a plurality of connection conductors 7 that each connect the corresponding wiring layers, and a plurality of insulating layer fixing members 10.

Since the plurality of insulating layers 2 and 3, the wiring layers 4, 5, and 6, and the plurality of connection conductors 7 are similar to those of the wiring board 1 in FIG. 1, they are given the same reference numerals and are not described.

The third insulating layer 22, the fourth insulating layer 23, and the fifth insulating layer 24 have the same structure as the first insulating layer 2. The third insulating layer 22 is disposed on a front surface side of the first insulating layer 2. The fourth insulating layer 23 and the fifth insulating layer 24 are disposed on a back surface side of the second insulating layer 3 in this order.

Wiring Layers

The fourth wiring layer 25 is disposed between the fourth insulating layer 23 and the fifth insulating layer 24. The fifth wiring layer 26 is disposed on a front surface side of the third insulating layer 22. The sixth wiring layer 27 is disposed on a back surface side of the fifth insulating layer 24.

The fifth wiring layer 26 includes terminals 26A and 26B that are electrically connected to the outside. The sixth wiring layer 27 includes terminals 27A and 27B that are electrically connected to the outside. Each of the terminals 26A, 26B, 27A, and 27B is shown as being fixed to its corresponding insulating layer in its entirety. Since the terminals 26A, 26B, 27A, and 27B have relatively small areas, and stress that is generated due to differences between the thermal expansion coefficients is small even if each of the terminals 26A, 26B, 27A, and 27B is fixed to its corresponding insulating layer in its entirety, each of the terminals 26A, 26B, 27A, and 27B may be joined to its corresponding insulating layer. However, since each of the terminals 26A, 26B, 27A, and 27B only needs to be connected to its corresponding wiring layer by its corresponding connection conductor 7, for the reason that it is no longer necessary to consider the stress that is generated due to differences, between the thermal expansion coefficients, it is desirable that each of the terminals 26A, 26B, 27A, and 27B not be fixed to its corresponding insulating layer.

In the embodiment, the first wiring layer 4 includes a main wiring layer 4A and an auxiliary wiring layer 4B that is separated from the main wiring layer 4A; the second wiring layer 5 includes a main wiring layer 5A and an auxiliary wiring layer 5B that is separated from the main wiring layer 5A; the third wiring layer 6 includes a main wiring layer 6A and an auxiliary wiring layer 6B that is separated from the main wiring layer 6A; and the fourth wiring layer 25 includes a main wiring layer 25A and an auxiliary wiring layer 25B that is separated from the main wiring layer 25A.

The main wiring layers 4A, 5A, 6A, and 25A are each a wiring layer where a wiring pattern of, for example, a coil is formed. Since each of the main wiring layers 4A, 5A, 6A, and 25A has a relatively large area, they each include unfixing regions B shown in FIG. 1.

The auxiliary wiring layers 4B, 5B, 6B, and 25B are each a wiring layer for connecting corresponding main wiring layers to each other in a thickness direction. For example, the auxiliary wiring layer 4B of the first wiring layer 4 electrically connects the main wiring layer 5A of the second wiring layer 5 and the main wiring layer 6A of the third wiring layer 6 to each other via the connection conductor 7.

Similarly to the terminals 26A, 26B, 27A, and 27B, the auxiliary wiring layers 4B, 5B, 6B, and 25B each have a relatively small area, with a maximum distance from its gravity center to its outer edge in plan view being 7 mm or less. Therefore, each of the auxiliary wiring layers 4B, 5B, 6B, and 25B may be fixed in its entirety to an insulating layer on a front surface side or on a back surface side in plan view without including unfixing regions B. In this case, each of the auxiliary wiring layers 4B, 5B, 6B, and 25B includes only a fixing region A.

Insulating Layer Fixing Members

The insulating layer fixing members 10 are members that join and fix adjacent insulating layers (for example, the first insulating layer 2 and the second insulating layer 3) to each other in the thickness direction. Each insulating layer fixing member 10 is disposed between corresponding insulating layers. Each insulating layer fixing member 10 is disposed so as to surround a corresponding one of the first wiring layer 4, the second wiring layer 5, the third wiring layer 6, and the fourth wiring layer 25 as viewed from the thickness direction.

Each insulating layer fixing member 10 includes two metallized layers 10A and a joining portion 10B.

The two metallized layers 10A are disposed between a back surface of one of two insulating layers that are joined to each other (for example, a back surface of the first insulating layer 2) and a front surface of the other insulating layer (for example, a front surface of the second insulating layer 3).

Each joining portion 10B is disposed between the two metallized layers 10A, and joins the two metallized layers 10A to each other in the thickness direction.

The material of each metallized layer 10A may contain, for example, tungsten or molybdenum as a main constituent. The material of each joining portion 10B may be the same as the material of the joining portion 7B of each connection conductor 7.

The plurality of insulating layer fixing members 10 may include insulating layer fixing members 10 that are formed from a resin adhesive, such as an epoxy resin adhesive or a silicone resin adhesive. Each insulating layer fixing member 10 may be formed by using a paste containing ceramic. When resin or ceramic is used, the metallized layers 10A need not be formed.

In order to seal and fix portions between the insulating layers, in addition to providing the insulating layer fixing members 10 that are provided between corresponding insulating layers, an insulating layer fixing member 10 that covers all at once a side portion of the wiring board over the plurality of insulating layers may be provided. Alternatively, instead of disposing each insulating layer fixing member 10 between corresponding insulating layers, it is possible to provide only the insulating layer fixing member that covers all at once a side portion of the wiring board over the plurality of insulating layers.

Effects

The embodiment described in detail above provides the following effects.

(3a) Since each of the wiring layers 4, 5, 6, and 25 is sealed by its corresponding insulating layer fixing member 10, oxidation of the wiring layers 4, 5, 6, and 25 and short circuits between wiring layers caused by moisture in the air are suppressed. As a result, it is possible to increase the reliability of the wiring board 1.

### D. Other Embodiments

Although embodiments of the present disclosure are described above, the present disclosure is not limited to the above-described embodiments, and may obviously take various forms.

(4a) In the wiring board 1 of the above-described embodiment, each wiring layer fixing member 9 need not be provided between the corresponding wiring layer and the corresponding insulating layer. That is, each wiring layer may include only the unfixing regions B without including the fixing regions A.

(4b) In the wiring board 1 of the above-described embodiment, the fixing regions A of the corresponding wiring layers and the unfixing regions B of the corresponding wiring layers may be disposed at locations that do not correspond with each other in plan view. That is, the wiring layer fixing members 9 may be disposed at locations that do not correspond with each other at each of the layers.

(4c) In the wiring boards 1 and 11 of the embodiments, each metal member 7A may contact the inner wall of a corresponding one of the insulating layer 2 that forms the through hole 2A and the insulating layer 3 that forms the through hole 3A, and each metal member BA may contact the inner wall of a corresponding one of the insulating layer 2 that forms the through hole 2A and the insulating layer 3 that forms the through hole 3A. The shape of each metal member 7A and the shape of each metal member 8A as viewed in the thickness direction may be the same as or may differ from the shape of the through hole 2A or the shape of the through hole 3A. Each metal member 7A may be joined to the inner wall of a corresponding one of the insulating layer 2 that forms the through hole 2A and the insulating layer 3 that forms the through hole 3A by the corresponding joining portion 7B, and each metal member 8A may be joined to the inner wall of a corresponding one of the insulating layer 2 that forms the through hole 2A and the insulating layer 3 that forms the through hole 3A by the corresponding joining portion 8B.

(4d) In the wiring boards 1, 11, and 21 of the above-described embodiments, the volume of the metal member 7A of each connection conductor 7 is smaller than the volume of each joining portion 7B, and the volume of the metal member 8A of each connection conductor 8 is smaller than the volume of each joining portion 8B.

(4e) In the wiring boards 1, 11, and 21 of the above-described embodiments, the material of each insulating layer is not limited to ceramic. For example, each insulating layer may contain, for example, a resin or glass as a main constituent.

(4f) In the wiring board 1 of the above-described embodiment, as each wiring layer fixing member 9, an adhesive may be used. As the adhesive in this case, a resin adhesive, such as an epoxy resin adhesive or a silicone resin adhesive, may be selected.

(4g) In the wiring board 21 of the above-described embodiment, each of the auxiliary wiring layers 4B, 5B, 6B, and 25B may include both a fixing region A and an unfixing region B. Alternatively, each of the auxiliary wiring layers 4B, 5B, 6B, and 25B may include only an unfixing region B.

(4h) The wiring boards 1, 11, and 21 of the above-described embodiments allow a planar transformer to be formed. That is, the first wiring layer and the second wiring layer may be such that a coil-like wiring pattern is provided at an outer edge portion of the insulating layer. Alternatively, a central portion of an insulating layer may include a core insertion hole that extends through an inner side of a wire-wound winding pattern having the form of a coil. For example, a magnetic-body core, such as a ferrite magnetic-body core, may be inserted into the core insertion hole.

(4i) Although, in the wiring boards 1, 11, and 21 of the above-described embodiments, the insulating layers are shown as having the same thickness and the wiring layers are shown as having the same thickness, the insulating layers may have different thicknesses and the wiring layers may have different thicknesses. The wiring layers may have different occupied areas.

(4j) The function of one structural element in the above-described embodiments may be distributed among a plurality of structural elements, or the functions of a plurality of structural elements may be combined in one structural element. A part of the structure of an embodiment described above may be omitted. At least part of the structure of an embodiment described above may be, for example, added to or replaced by the structure of another embodiment described above. Various modes included in the technical idea that is specified from the wording in the scope of the claims correspond to embodiments of the present disclosure.

What is claimed is:

1. A wiring board comprising:
at least one insulating layer that has a front surface and a back surface, the at least one insulating layer defining a through hole that extends through the insulating layer in a thickness direction;
a first wiring layer disposed adjacent to a front surface side of the at least one insulating layer;
a second wiring layer disposed adjacent to a back surface side of the at least one insulating layer; and
a connection conductor electrically connecting the first wiring layer to the second wiring layer, the connection conductor including a metal member disposed in the through hole of the at least one insulating layer, and a joining portion that covers at least a part of an outer surface of the metal member and that joins the metal member to the first wiring layer and to the second wiring layer.

2. The wiring board according to claim 1, wherein a volume of the metal member is greater than a volume of the joining portion.

3. The wiring board according to claim 1, wherein the metal member is a block body or a spherical body.

4. The wiring board according to claim 1, wherein, when projected onto a virtual plane that is perpendicular to the thickness direction of the insulating layer, an area of the metal member is smaller than an opening area of the through hole.

5. The wiring board according to claim 1, wherein the metal member is not fixed to an inner wall of the insulating layer that defines the through hole.

6. The wiring board according to claim 1, wherein at least one of the first wiring layer and the second wiring layer includes an unfixing region that is not fixed to the at least one insulating layer adjacent thereto and a fixing region that is fixed to the at least one insulating layer adjacent thereto.

7. The wiring board according to claim 1, wherein the first wiring layer and the second wiring layer are not fixed to the insulating layer adjacent thereto.

8. The wiring board according to claim 1, wherein a main constituent of the first wiring layer and the second wiring layer is copper.

9. The wiring board according to claim 1, wherein a main constituent of the insulating layer is ceramic.

10. A planar transformer comprising:
a wiring board including
at least one insulating layer that has a front surface and a back surface, the at least one insulating layer defining a through hole that extends through the insulating layer in a thickness direction;
a first wiring layer disposed adjacent to a front surface side of the at least one insulating layer;
a second wiring layer disposed adjacent to a back surface side of the at least one insulating layer; and
a connection conductor electrically connecting the first wiring layer to the second wiring layer, the connection conductor including a metal member disposed in the through hole of the at least one insulating layer, and a joining portion that covers at least a part of an outer surface of the metal member and that joins the metal member to the first wiring layer and to the second wiring layer.

11. A method of manufacturing a wiring board that includes at least one insulating layer that has a front surface and a back surface, a first wiring layer disposed adjacent to a front surface side of the at least one insulating layer, a second wiring layer that is disposed adjacent to a back surface side of the at least one insulating layer, and a connection conductor electrically connecting the first wiring layer to the second wiring layer, the method comprising:
a step of forming a through hole in the insulating layer, the through hole extending through the insulating layer in a thickness direction;
a step of disposing a metal member in the through hole, at least a part of an outer surface of the metal member being covered by a joining portion;
a step of disposing the first wiring layer adjacent to the front surface side of the insulating layer and disposing the second wiring layer adjacent to the back surface side of the insulating layer; and
a step of joining the metal member to the first wiring layer and to the second wiring layer with the joining portion.
